(19) United States
(12) Patent Application Publication
(10) Pub. No.: US 2013/0094228 A1
(43) Pub. Date: Apr. 18, 2013

(54) Electronic assembly and a LED retrofit lamp having the Electronic assembly

(71) Applicant: OSRAM AG, Muenchen (DE)

(72) Inventors: Shaoping Chen, Shenzhen (CN); Xiongqiang He, Shenzhen (CN); Wuqiang Liao, Shenzhen (CN); Wei Tan, Shenzhen (CN)

(73) Assignee: OSRAM AG, Muenchen (DE)

(21) Appl. No.: 13/650,175

(22) Filed: Oct. 12, 2012

(30) Foreign Application Priority Data
Oct. 14, 2011 (CN) 201110312678.X

(51) Int. Cl. H05K 1/18; F21V 21/00

(52) U.S. Cl. 362/382; 174/260

(57) ABSTRACT

The present invention relates to an electronic assembly which includes a printed circuit board and at least two I-type inductors arranged on the printed circuit board, the I-type inductor include an I-type magnetic pillar, respectively, wherein the magnetic pillars of the at least two I-type inductors are arranged in such a manner that a first end surfaces of the magnetic pillars are non-coplanar with each other and/or the second end surfaces of the magnetic pillars are non-coplanar with each other. In addition, the present invention further relates to an LED retrofit lamp having such electronic assembly.

### CROSS REFERENCE TO RELATED APPLICATION

This application claims the priority of Chinese patent application no. 201110312678.X filed on Oct. 14, 2011 the entire disclosures of which are incorporated herein by reference.

### TECHNICAL FIELD

The present disclosure relates to an electronic assembly, and also relates to an LED retrofit lamp having such electronic assembly for.

### BACKGROUND ART

LED illumination has irreplaceable advantages, such as energy saving, low power consumption, and electrical-to-optical conversion efficiency near 100%. It can save more than 80% energy as compared with a traditional light source with the same illuminating efficiency and has a longer service lifetime. In view of the above advantages, LEDs are used increasingly more as light sources, seen in the use of LED retrofit lamps in the market. Such LED retrofit lamps have the same appearance and profile as traditional light sources such as incandescents or lamp tubes, thus they can be more applicable to the existing illuminating systems as a light source. With the improvement in people's life, the different requirements are put forward on the function of the LED retrofit lamp, for example, the LED retrofit lamp should be capable of dimming in order to produce different ambiances for different situations. However, in the prior art, a loud noise is caused when the LED retrofit lamp interacts with a leading phase-cut dimmer, because an inrush current will appear during the phase-cut dimming, which leads to a strong and sudden change to the magnetic field intensity, and adjacent inductors will vibrate due to the Lorentz force, which produces the noise. In addition, as there are undesirable gaps and looseness between the winding and the mechanical structure of the inductor in the inductor, it negatively provides a space for vibration, and further noise, when under the effect of the electromagnetic force.

In order to solve the problems, in the prior art, the inductor is usually immersed in oil to secure the winding and seal the gap to reduce vibration. However, not all noise can be removed because there will be still parts of the winding which have not been fastened by the oil. Furthermore, there is still a magnetic field strong enough to cause the noise when the inrush current is produced during phase-cut dimming with the leading phase-cut dimmer.

In addition, in the existing solutions, the noise is also decreased by trying to increase the distance between the inductors. In a Helmholtz winding simulation experimentation, based on the Biot-Savart law, once the distance between two inductors increases slightly, the electromagnetic induction between the inductors will quickly decrease. But the method of simply increasing the distance between two inductors is not feasible in the LED retrofit lamp, because the space in the LED retrofit lamp is limited and cannot provide a sufficient space to the inductors.

### SUMMARY OF THE INVENTION

In order to solve the technical problems above, the present invention provides an electronic assembly that effectively avoids mutual electromagnetic induction between inductors without prominently increasing the distance between the inductors, so as to reduce the vibration and lower down the noise. In addition, the present invention further provides an LED retrofit lamp having such electronic assembly. The LED retrofit lamp has a compact structure, occupies a small installation space and also produces small noise when in a dimming operation by a phase-cut dimmer.

The first object of the present invention is accomplished via an electronic assembly. The electronic assembly includes a printed circuit board and at least two I-type inductors arranged on the printed circuit board, the I-type inductor includes an I-type magnetic core with a magnetic pillar, respectively, wherein the magnetic pillars of the at least two I-type inductors are arranged in such a manner that a first end surfaces of the magnetic pillars are non-coplanar with each other and/or a second end surfaces of the magnetic pillars are non-coplanar with each other. Thereby, the distance between the windings of the neighboring inductors is increased without increasing the distance between the inductors, consequently, the electromagnetic induction between the inductors prominently decreases, and further the vibration is reduced and the noise is lowered down.

According to a preferred solution of the present invention, the printed circuit board has a first mounting surface and a second mounting surface opposite to each other, wherein the at least two I-type inductors are arranged simultaneously on one of the first mounting surface and the second mounting surface. Preferably, a height difference between the first end surfaces, and that between the second end surfaces of the magnetic pillars of I-type inductors are at least 2 mm, respectively. As a result, the distance between the windings of the neighboring inductors is increased without increasing the distance between the inductors, consequently, the electromagnetic induction between the inductors prominently decreases, and further the vibration is reduced and the noise is lowered down.

Preferably, a distance between the I-type inductors is at least 0.5 mm. This further decreases the electromagnetic induction between the inductors, and further reduces the vibration and lower down the noise.

According to another preferred solution of the present invention, the at least two I-type inductors are arranged on the first mounting surface and the second mounting surface, respectively. This further improves the space utilization ratio of the electronic assembly of the present invention and results in a compact structure and a small installation space of the electronic assembly.

Advantageously, neighboring I-type inductors on the printed circuit board are arranged in such a manner that the magnetic pillars thereof form a predetermined angle to each other. Preferably, the neighboring I-type inductors are arranged on the printed circuit board in such a manner that the magnetic pillar of one I-type inductor is perpendicular to the printed circuit board, and the magnetic pillar of the other I-type inductor is parallel with the printed circuit board. Further preferably, the neighboring I-type inductors are so arranged that the magnetic pillars thereof slope with respect to the printed circuit board, respectively, and the first end surfaces of the magnetic pillars of the I-type inductors face different directions, respectively. In such arrangement, without increasing the distance between the inductors, the distance between the windings of the neighboring inductors is increased as much as possible so as to decrease the electromagnetic induction between the inductors, and further to reduce the vibration and lower down the noise.

Advantageously, the I-type inductors on the printed circuit board are arranged in such a manner that the magnetic pillars thereof are parallel with the printed circuit board and the first end surfaces of the magnetic pillars face different directions.

The other object of the present invention is accomplished via an LED retrofit lamp having such electronic assembly for. The LED retrofit lamp has a compact structure, occupies a small installation space, and also produces a small noise in dimming operation by a phase-cut dimmer.

### BRIEF DESCRIPTION OF THE DRAWINGS

The accompanying drawings constitute a part of the present Description and are used to provide further understanding of the present invention. Such accompanying drawings illustrate the embodiments of the present invention and are used to describe the principles of the present invention together with the Description. In the accompanying drawings the same components are represented by the same reference numbers. As shown in the drawings:

FIG. 1 is a schematic diagram of a first embodiment of an electronic assembly of the present invention;

FIG. 2 is a schematic diagram of a variant of the first embodiment of the electronic assembly of the present invention;

FIG. 3 is a schematic diagram of another variant of the first embodiment of the electronic assembly of the present invention; and

FIG. 4 is a schematic diagram of a second embodiment of an electronic assembly of the present invention.

### DETAILED DESCRIPTION OF THE EMBODIMENTS

It is to be understood that the invention is not limited to the particular embodiments described in further detail below and as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, a limited number of the exemplary methods and materials are described herein.

It must be noted that as used herein and in the appended claims, the singular forms “a”, “an”, and “the” include plural referents unless the context clearly dictates otherwise.

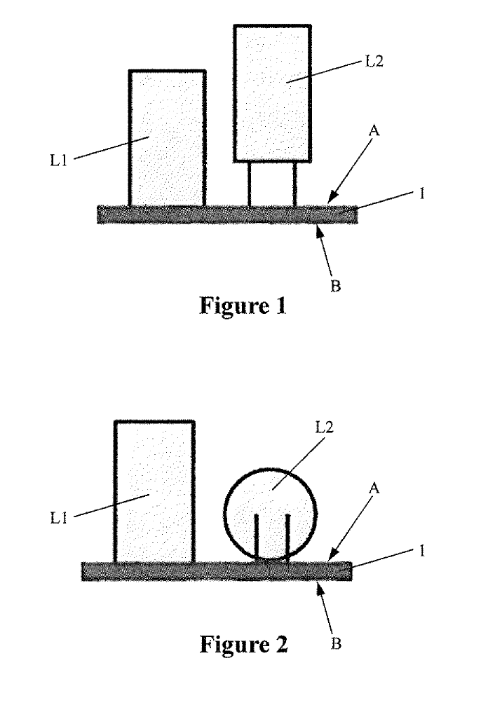

FIG. 1 is a schematic diagram of a first embodiment of an electronic assembly of the present invention. As can be seen from FIG. 1, the electronic assembly comprises a printed circuit board 1 having a first mounting surface A and a second mounting surface B and two inductors L1, L2 arranged on the printed circuit board 1. The inductors L1, L2 are I-type inductors including an I-type magnetic core with a magnetic pillar, wherein two end surfaces of respective magnetic pillar are formed to be a first end surface and a second end surfaces, respectively. In the first embodiment, the I-type inductors L1, L2 are both arranged at one side of the printed circuit board 1, i.e., both are arranged on the first mounting surface A, and of course, both also can be arranged on the first mounting surface B, and the I-type inductors L1, L2 on the printed circuit board 1 are arranged in such a manner that the magnetic pillars thereof are simultaneously perpendicular to the printed circuit board 1. In the present embodiment, the magnetic pillars of the I-type inductors L1, L2 are arranged in such a manner that the first end surfaces thereof are non-coplanar with each other and the second end surfaces are non-coplanar with each other, and that a height difference between the first end surfaces, and that between the second end surfaces are at least 2 mm, respectively. A distance between I-type inductors L1, L2 is at least 0.5 mm.

FIG. 2 is a schematic diagram of a variant of the first embodiment of the electronic assembly of the present invention, which is different from the electronic assembly in FIG. 1 in that the magnetic pillar of the I-type inductor L1 is arranged to be perpendicular to the printed circuit board 1, and the magnetic pillar of the I-type inductor L2 is arranged to be parallel with the printed circuit board 1. As a result, the I-type inductors L1, L2 have the first end surfaces non-coplanar with each other and non-coplanar the second end surfaces non-coplanar with each other. Of course, the magnetic pillar of the I-type inductor L2 does not have to be arranged to be parallel with the printed circuit board 1, but it may be arranged to slope with respect to the printed circuit board 1 as long as the I-type inductors L1, L2 are assured to have the first end surfaces non-coplanar with each other and the second end surfaces non-coplanar with each other.

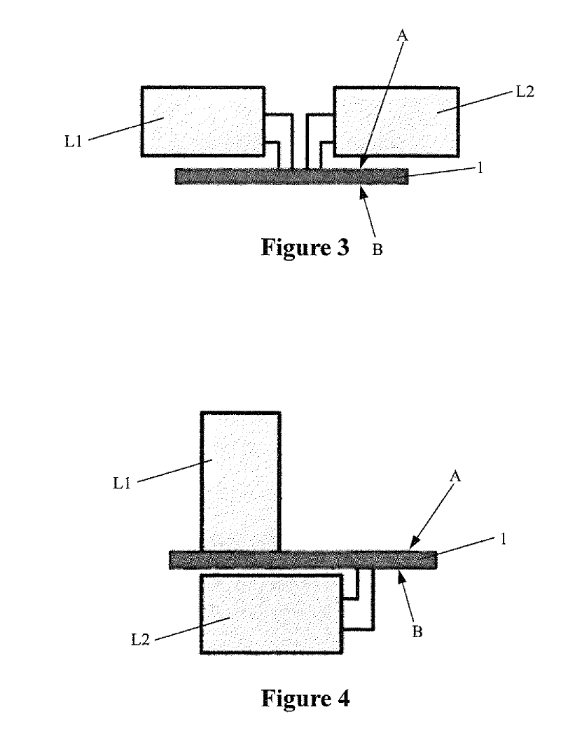

FIG. 3 is a schematic diagram of another variant of the first embodiment of the electronic assembly of the present invention, which is different from the electronic assembly in FIG. 1 in that the magnetic pillars of the I-type inductors L1, L2 are arranged to be parallel with the printed circuit board 1, respectively, and the first end surfaces of the I-type inductors L1, L2 face different directions. Of course, the magnetic pillars of the I-type inductors L1, L2 also may be arranged to slope with respect to the printed circuit board 1 as long as the I-type inductors L1, L2 are assured to have the first end surfaces non-coplanar with each other and the second end surfaces non-coplanar with each other.

FIG. 4 is a schematic diagram of a second embodiment of an electronic assembly of the present invention. As can be seen from FIG. 4, the two I-type inductors L1, L2 are arranged on the first mounting surface A and the second mounting surface B, respectively. The magnetic pillar of the I-type inductor L1 on the first mounting surface A is arranged to be perpendicular to the printed circuit board 1, and the magnetic pillar of the I-type inductor L2 on the second mounting surface B is arranged to be parallel to the printed circuit board 1.

In the solutions of the present invention, the magnetic pillars of the I-type inductors on respective mounting surfaces may be arranged in various directions with respect to the printed circuit board 1, as long as the I-type inductors are assured to have the first end surfaces non-coplanar with each other and the second end surfaces non-coplanar with each other.

The above is merely preferred embodiments of the present invention but not to limit the present invention. For the person skilled in the art, the present invention may have various alterations and changes. Any alterations, equivalent substitutions, improvements, within the spirit and principle of the present invention, should be covered in the protection scope of the present invention.

Thus, specific compositions and methods of the electronic assembly and an LED retrofit lamp having the electronic assembly have been disclosed. It should be apparent, however, to those skilled in the art that many more modifications besides those already described are possible without departing from the inventive concepts herein. The inventive subject matter, therefore, is not to be restricted except in the spirit of the disclosure. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

### LIST REFERENCE SIGNS

1 printed circuit board
L1, L2 I-type inductor
A first mounting surface
B second mounting surface

1. An electronic assembly, comprising:
a printed circuit board and at least two I-type inductors arranged on the printed circuit board, the at least two I-type inductors each including an I-type magnetic core with a magnetic pillar respectively,
wherein at least one of a first end surface and a second end surface of the respective magnetic pillar are non-coplanar with respect to each other.

2. The electronic assembly according to claim 1, wherein the printed circuit board has a first mounting surface and a second mounting surface opposite to each other, wherein the at least two I-type inductors are arranged simultaneously on one of the first mounting surface and the second mounting surface.

3. The electronic assembly according to claim 2, wherein a height difference between the first end surfaces of the magnetic pillars, and that between the second end surfaces of the magnetic pillars of the I-type inductors are at least 2 mm, respectively.

4. The electronic assembly according to claim 2, wherein a distance between the I-type inductors is at least 0.5 mm.

5. The electronic assembly according to claim 1, wherein the printed circuit board has a first mounting surface and a second mounting surface opposite to each other, wherein the at least two I-type inductors are arranged on the first mounting surface and the second mounting surface respectively.

6. The electronic assembly according to claim 2, wherein the magnetic pillars of the I-type inductors form a predetermined angle to each other.

7. The electronic assembly according to claim 6, wherein the magnetic pillar of one of the I-type inductors is perpendicular to the printed circuit board and the magnetic pillar of the other I-type inductor is parallel with the printed circuit board.

8. The electronic assembly according to claim 4, wherein the magnetic pillars of the I-type inductors are oblique with respect to the printed circuit board, respectively.

9. The electronic assembly according to claim 2, wherein the magnetic pillars of the I-type inductors are parallel with the printed circuit board and the magnetic pillars face away from each other.

10. An LED retrofit lamp having an electronic assembly, the assembly comprising:
a printed circuit board and at least two I-type inductors arranged on the printed circuit board, the I-type inductor including an I-type magnetic core with a magnetic pillar, respectively,
wherein the magnetic pillars of the at least two I-type inductors are arranged in such a manner that a first end surfaces of the magnetic pillars are non-coplanar with each other and/or a second end surfaces of the magnetic pillars are non-coplanar with each other.
